(19) United States
(12) Patent Application Publication
(10) Pub. No.: US 2023/0258416 A1
(43) Pub. Date: Aug. 17, 2023

(54) VAPOR CHAMBER AND METHOD FOR PRODUCING VAPOR CHAMBER

(71) Applicant: FURUKAWA ELECTRIC CO., LTD., Tokyo (JP)

(72) Inventor: Kengo TANAKA, Tokyo (JP)

(73) Assignee: FURUKAWA ELECTRIC CO., LTD., Tokyo (JP)

(21) Appl. No.: 18/002,908

(22) PCT Filed: Jun. 25, 2021
(86) PCT No.: PCT/JP2021/024251

§ 371 Date: Dec. 22, 2022

(30) Foreign Application Priority Data
Jun. 30, 2020 (JP) 2020-112762

(51) Int. Cl. F28F 3/12; F28D 15/02; F28D 15/04

(52) U.S. Cl. CPC F28F 3/12; F28D 15/0233; F28D 15/046; F28F 2255/08; F28F 2260/00

(57) ABSTRACT

A vapor chamber has a working fluid in an internal space formed between a first metal sheet and a second metal sheet, in which the first metal sheet includes a recessed channel and at least one projecting part. The recessed channel is provided at an inner surface of the first metal sheet; the projecting part projects from the inner surface of the first metal sheet toward the second metal sheet, and a top face of the projecting part abuts the second metal sheet. The vapor chamber includes at least one top face joining part and gap flow channel part, the top face joining part joins part of the top face of the projecting part and the second metal sheet, and the top face and the second metal sheet are separated at the gap flow channel part.

### TECHNICAL FIELD

The present disclosure relates to a vapor chamber and a manufacturing method of a vapor chamber.

### BACKGROUND ART

Electronic components such as semiconductor elements mounted in electrical/electronic devices such as notebook computers, digital cameras and mobile telephones are in a trend of increasing heat generation amount, due to the high-density mounting accompanying improved performance. In order to correctly drive an electrical/electronic device over a long period, it is necessary to efficiently cool the electronic components.

For example, Patent Document 1 discloses a vapor chamber having a first metal sheet and a second metal sheet, and including a liquid flow passage part in a sealed space provided between the first metal sheet and the second metal sheet. In the vapor chamber of Patent Document 1, for each groove constituting the liquid flow passage part, the width of a first communication groove is larger than the width of a first main flow groove and the width of a second main flow groove, the width of a second communication groove is larger than the width of the second main flow groove and the width of a third main flow groove, the depth of the first communication groove is deeper than the depth of the first main flow groove and the depth of the second main flow groove, and the depth of the second communication groove is deeper than the depth of the second main flow groove and the depth of the third main flow groove.

In the vapor chamber of Patent Document 1, the first metal sheet and the second metal sheet are joined by diffusion bonding, brazing or the like. When performing diffusion bonding or brazing, the first metal sheet and the second metal sheet are heat treated and annealed as a whole. Since the entirety of the vapor chamber is annealed in this way, the mechanical strength of the vapor chamber decline. In addition, in the vapor chamber of Patent Document 1, an improvement in heat transport efficiency is achieved by each groove constituting the liquid flow passage part satisfying a predetermined relationship. However, it is insufficient in addressing the demand of cooling performance of the electrical/electronic device which are increasing in recent years.

Patent Document 1: Japanese Unexamined Patent Application, Publication No. 2019-158323

### DISCLOSURE OF THE INVENTION

### Problems to be Solved by the Invention

An object of the present disclosure is to provide a vapor chamber superior in mechanical strength and heat transport characteristic and a manufacturing method of the vapor chamber.

### Means for Solving the Problems

According to a first aspect of the present disclosure, a vapor chamber includes a working fluid in an internal space formed between a first metal sheet and a second metal sheet, in which the first metal sheet comprises a recessed channel and at least one projecting part; the recessed channel is provided at an inner surface of the first metal sheet; the projecting part projects from the inner surface of the first metal sheet toward the second metal sheet, and a top face of the projecting part abuts the second metal sheet; the vapor chamber includes at least one top face joining part and gap flow channel part; the top face joining part joins part of the top face of the projecting part and the second metal sheet; and the top face and the second metal sheet are separated at the gap flow channel part.

According to a second aspect of the present disclosure, in the vapor chamber as described in the first aspect, the gap flow channel part is provided between a top face abutting part not joined to the second metal sheet in the top face of the first metal sheet, and an inner surface abutting part of the second metal sheet abutting the top face abutting part; the gap flow channel part has a sealed part at a top face joining part side of the top face abutting part; and the gap flow channel part has an opening part at a projecting part lateral face side of the top face abutting part.

According to a third aspect of the present disclosure, in the vapor chamber as described in the second aspect, the gap flow channel part has a longer gap length from the sealed part to the opening part than a gap width between the top face abutting part and the inner surface abutting part.

According to a fourth aspect of the present disclosure, in the vapor chamber as described in the second or third aspect, the gap flow channel part has an average value of a gap width between the top face abutting part and the inner surface abutting part of 1.0 μm or more and 100.0 μm or less.

According to a fifth aspect of the present disclosure, in the vapor chamber as described in any one of the second to fourth aspects, the gap flow channel part has an average value of a gap length from the sealed part to the opening part of 40.0 μm or more.

According to a sixth aspect of the present disclosure, in the vapor chamber as described in any one of the second to fifth aspects, the gap flow channel part includes a gap enlarged part at a sealed part side; and an average value of a gap width between the top face abutting part and the inner surface abutting part at the gap enlarged part is larger than an average value of the gap width at the gap flow channel part other than the gap enlarged part.

According to a seventh aspect of the present disclosure, in the vapor chamber as described in any one of the first to sixth aspects, a ratio (t2/t1) of a sheet thickness t2 at the projecting part of the first metal sheet relative to a sheet thickness t1 at the recessed channel of the first metal sheet is 0.1 or more and 10.0 or less.

According to an eighth aspect of the present disclosure, in the vapor chamber as described in any one of the first to seventh aspects, the projecting part extends along a longitudinal direction of the vapor chamber.

According to a ninth aspect of the present disclosure, in the vapor chamber as described in any one of the first to eighth aspects, the vapor chamber includes a plurality of the top face joining parts at one of the projecting parts.

According to a tenth aspect of the present disclosure, in the vapor chamber as described in any one of the first to ninth aspects, the second metal sheet includes at least one projecting part at an inner surface; and the projecting part of the second metal sheet projects from the inner surface of the second metal sheet toward the first metal sheet, and a top face of the projecting part abuts the recessed channel of the first metal sheet.

According to an eleventh aspect of the present disclosure, a manufacturing method of the vapor chamber as described in any one of the first to tenth aspects includes: a laser bonding step of forming the top face joining part by laser.

According to a twelfth aspect of the present disclosure, the manufacturing method of the vapor chamber as described in the eleventh aspect further includes a laser welding step of welding an outer edge of the first metal sheet and an outer edge of the second metal sheet by laser, before or after the laser bonding step.

According to a thirteenth aspect of the present disclosure, the manufacturing method of the vapor chamber as described in the eleventh or twelfth aspect further includes a press processing step of forming the recessed channel and the projecting part of the first metal sheet by press molding, prior to the laser bonding step and the laser welding step.

### Effects of the Invention

According to the present disclosure, it is possible to provide a vapor chamber superior in mechanical strength and heat transport characteristic and a manufacturing method of the vapor chamber.

### BRIEF DESCRIPTION OF THE DRAWINGS

FIG. 1 is a perspective view showing an example of a vapor chamber according to a first embodiment.

FIG. 2 is an enlarged cross-sectional view of a plane A in FIG. 1.

FIG. 3 is an enlarged cross-sectional view showing another example of a second metal sheet constituting the vapor chamber according to the first embodiment.

FIG. 4 is a perspective view showing another example of a projecting part constituting the vapor chamber according to the first embodiment.

FIG. 5 is a perspective view showing an example of a vapor chamber according to a second embodiment.

FIG. 6 is an enlarged cross-sectional view of a plane B in FIG. 5.

FIG. 7 is an enlarged cross-sectional view showing another example of a projecting part constituting the vapor chamber according to the second embodiment.

### PREFERRED MODE FOR CARRYING OUT THE INVENTION

Hereinafter, an embodiment will be explained in detail.

The present inventors, as a result of thorough examination, achieved an improvement in mechanical strength and heat transport characteristics, by focusing on the configuration of a joining part which joins the first metal sheet and the second metal sheet.

A vapor chamber of the embodiment includes a working fluid in an internal space formed between a first metal sheet and a second metal sheet, in which the first metal sheet comprises a recessed channel and at least one projecting part; the recessed channel is provided at an inner surface of the first metal sheet; the projecting part projects from the inner surface of the first metal sheet toward the second metal sheet, and a top face of the projecting part abuts the second metal sheet; the vapor chamber includes at least one top face joining part and gap flow channel part; the top face joining part joins part of the top face of the projecting part and the second metal sheet; and the top face and the second metal sheet are separated at the gap flow channel part.

### First Embodiment

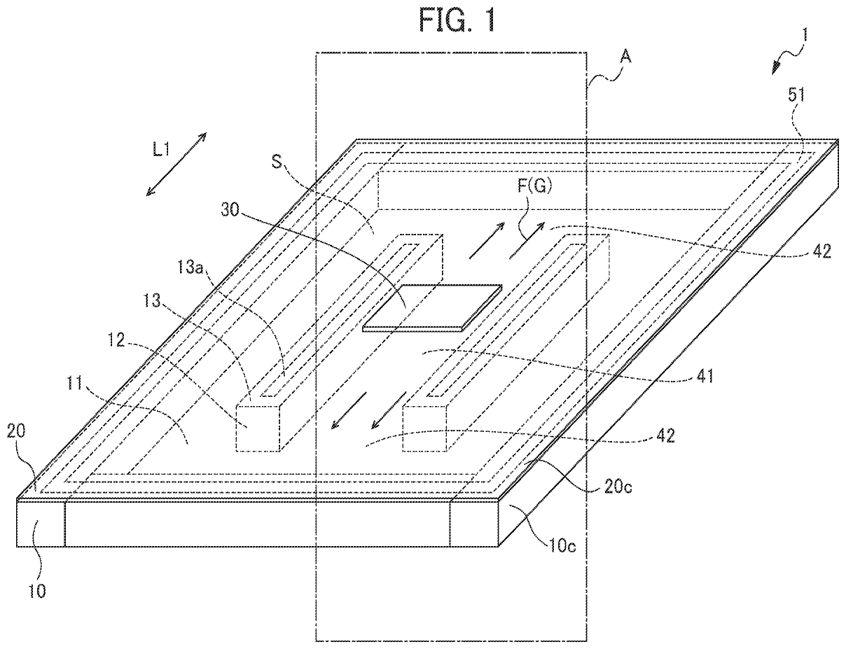

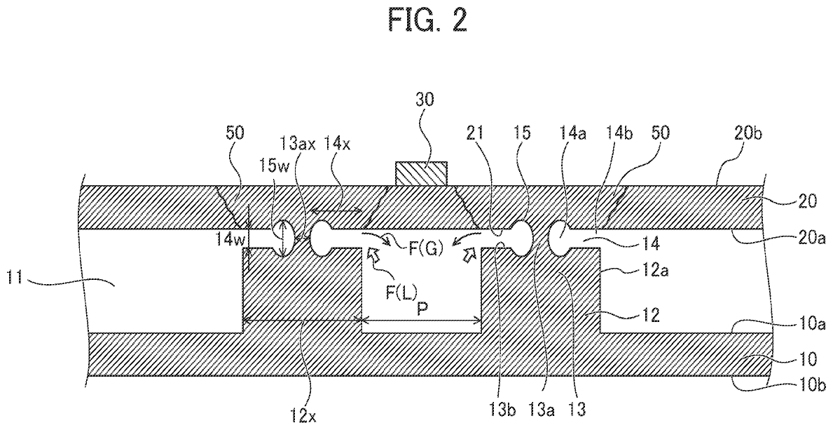

FIG. 1 is a perspective view showing an example of a vapor chamber according to a first embodiment. FIG. 2 is an enlarged cross-sectional view of a plane A in FIG. 1. For convenience, FIG. 1 shows an aspect partially penetrating so that the internal structure of the vapor chamber is understood. In addition, FIGS. 1 and 2 show the flow direction of the gas-phase working fluid F(G) by the black arrows, and show the flow direction of the liquid-phase working fluid F(L) by the white arrows.

As shown in FIGS. 1 and 2, the vapor chamber 1 of the first embodiment has a first metal sheet 10 and a second metal sheet 20. The first metal sheet 10 and the second metal sheet 20 are joined so that an inner surface 10a of the first metal sheet 10 and an inner surface 20a of the second metal sheet 20 are opposing. In other words, the first metal sheet 10 and the second metal sheet 20 have the insides closed. In addition, the vapor chamber 1 has a working fluid in an internal space S formed between the first metal sheet 10 and the second metal sheet 20. The internal space S is sealed by the first metal sheet 10 and the second metal sheet 20. The working fluid is enclosed in the internal space S provided inside of the vapor chamber 1.

As the working fluid enclosed in the internal space S, pure water, ethanol, methanol, acetone, etc. can be exemplified from the viewpoint of cooling performance of the vapor chamber 1.

The first metal sheet 10 constituting the vapor chamber 1 includes a recessed channel 11 and at least one projecting part 12.

As shown in FIG. 1, the recessed channel 11 is provided at the inner surface 10a of the first metal sheet 10. The recessed channel 11 provided on the side of the inner surface 10a indents from an outer edge 10c of the first metal sheet 10 along the center of the inner surface 10a. For example, the recessed channel is a space from the internal space S excluding the projecting part 12 and gap flow channel part 14. The gas-phase working fluid mainly flows in the recessed channel 11.

The projecting part 12 projects from the inner surface 10a of the first metal sheet 10 toward the inner surface 20a of the second metal sheet 20. A top face 13 of the projecting part 12 abuts the inner surface 20a of the second metal sheet 20. For example, the projecting part 12 is a square columnar shape.

As shown in FIG. 2, the vapor chamber 1 includes at least one top face joining part 13a and a gap flow channel part 14.

The top face joining part 13a joins part of the top face 13 of the projecting part 12 and the second metal sheet 20. In this way, at the abutting surface between the top face 13 of the projecting part 12 and the inner surface 20a of the second metal sheet 20, the top face joining part 13a joins part of the top face 13 of the projecting part 12 and part of the inner surface 20a of the second metal sheet 20.

The vapor chamber 1 locally possesses an annealed part 50 at a portion adjacent to the top face joining part 13a, rather than over the entirety of the vapor chamber 1. The annealed part 50 is produced by heating when forming the top face joining part 13a which joins the first metal sheet 10 and the second metal sheet 20. For example, as shown in FIG. 2, the vapor chamber 1 possesses the annealed part 50 formed at the second metal sheet 20 adjacent to the top face joining part 13a. The metallographic structure of the annealed part 50 and the metallographic structure of the portion other than the annealed part 50 clearly differ when observed by SEM.

The first metal sheet 10 and the second metal sheet 20 are joined via the top face joining part 13a. The length 13ax of the top face joining part 13a which joins part of the top face 13 and part of the inner surface 20a is smaller than the length 12x of the projecting part 12. From the viewpoint of suppressing a decline in mechanical strength of the vapor chamber 1, the ratio (13ax/12x) of the length 13ax of the top face joining part 13a relative to the length 12x of the projecting part 12 is preferably smaller than 0.5. The length 13ax of the top face joining part 13a and the length 12x of the projecting part 12 are distances in a direction perpendicular to the thickness direction of the vapor chamber 1, in a cross section of the vapor chamber 1 including the top face joining part 13a such as that shown in FIG. 2.

At the gap flow channel part 14, the top face 13 of the first metal sheet 10 and the second metal sheet 20 are separated. The liquid-phase working fluid flows in the gap flow channel part 14.

Such a gap flow channel part 14 is provided between the top face abutting part 13b of the top face 13 of the projecting part 12 and an inner surface abutting part 21 of the second metal sheet 20. The top face abutting part 13b of the first metal sheet 10 is a portion of the top face 13 of the first metal sheet 10 which is not joined to the inner surface 20a of the second metal sheet 20. The inner surface abutting part 21 of the second metal sheet 20 is a portion of the inner surface 20a of the second metal sheet 20 which abuts the top face abutting part 13b.

The top face abutting part 13b and the inner surface abutting part 21 are separably abutting each other without being joined. The gap flow channel part 14 is a gap occurring at the abutting of the top face abutting part 13b and the inner surface abutting part 21. It should be noted that, herein for convenience, a state in which the top face abutting part 13b and the inner surface abutting part 21 are clearly distanced is shown so as to facilitate understanding the gap flow channel part 14.

In addition, the gap flow channel part 14 has a sealed part 14a at a top face joining part 13a side of the top face abutting part 13b. The sealed part 14a is a portion at which the top face abutting part 13b and the top face joining part 13a connect, and is sealed by the top face joining part 13a. In addition, the gap flow channel part 14 has an opening part 14b at a projecting part lateral face side of the top face abutting part 13b. The projecting part lateral face side is a lateral face 12a side of the projecting part 12, which is a recessed channel 11 side. In this way, in the gap flow channel part 14, the top face joining part 13a side of the top face abutting part 13b is sealed, and the projecting part lateral face side of the top face abutting part 13b is open.

The gap flow channel part 14 is provided at a top face 13 side of the projecting part 12, between the recessed channel 11 and the top face joining part 13a. At the top face 13 side of the projecting part 12, the gap flow channel part 14 provided at the circumference of the top face joining part 13a extends in a direction perpendicular to the thickness direction of the vapor chamber 1. The gap flow channel part 14 communicates with the recessed channel 11 via the opening part 14b. More specifically, the gap flow channel part 14 communicates with the recessed channel 11 at a side of the second metal sheet 20.

The gap width 14w of the gap flow channel part 14 is very small compared to the groove interval p of the recessed channel 11. The gap width 14w of the gap flow channel part 14 is the distance between the top face abutting part 13b and the inner surface abutting part 21. The groove interval p of the recessed channel 11 is the distance between adjoining projecting parts 12 or the distance between a projecting part 12 and an outer edge 10c. As described above, the gap flow channel part 14 is a gap occurring at the abutting of the top face abutting part 13b and the inner surface abutting part 21, and the gap width 14w of the gap flow channel part 14 is very small. For this reason, the gap flow channel part 14 exhibits a capillary phenomenon relative to the liquid-phase working fluid.

The vapor chamber 1 cools the heat generating body 30 mainly by the following cooling path.

The heat generated by the heat generating body 30 thermally connected with the outer surface 20b of the second metal sheet 20 is transferred to the evaporation part 41 positioned at the inner surface 20a of the second metal sheet 20. The evaporation part 41 causes the liquid-phase working fluid flowing in the gap flow channel part 14 to evaporate and phase change to gas-phase working fluid as shown by the arrow F(G) as shown in FIG. 2, by the heat transferred from the heat generating body 30. The gas-phase working fluid heated by evaporation flows to the condensation part 42 at a position distanced from the evaporation part 41, as shown by the arrow F(G) in FIG. 1. In the course of the gas-phase working fluid flowing toward the condensation part 42, the temperature of the working fluid drops. In the condensation part 42, the gas-phase working fluid which has dropped in temperature is condensed and phase changes to the liquid-phase working fluid. The latent heat generated by phase change is transferred to the first metal sheet 10 or the second metal sheet 20, and is radiated to outside of the vapor chamber 1. The condensed liquid-phase working fluid easily infiltrates into the gap flow channel part 14 by the capillary phenomenon as shown by the arrow F(L) in FIG. 2. The liquid-phase working fluid migrates in the gap flow channel part 14 and returns to the evaporation part 41 again. By such favorable circulation of the liquid-phase working fluid and the gas-phase working fluid, the vapor chamber 1 can efficiently cool the heat generating body 30.

When the vapor chamber 1 includes the gap flow channel part 14 at the top face 13 side of the projecting part 12, the liquid-phase working fluid easily infiltrates the gap flow channel part 14 from the recessed channel 11 and the liquid-phase working fluid in the gap flow channel part 14 hardly leaks to outside of the gap flow channel part 14, by the capillary phenomenon of the gap flow channel part 14 relative to the liquid-phase working fluid. On the other hand, in a conventional vapor chamber not including such a gap flow channel part 14, since a configuration corresponding to the gap flow channel part 14 of the vapor chamber 1 is not provided, the liquid-phase working fluid flows in the recessed channel. In this way, compared to conventional, in the vapor chamber 1 including the gap flow channel part 14, the retention amount of the liquid-phase working fluid increases, and the recirculation amount of the working fluid increases. For this reason, the heat transport amount in the internal space S improves. Furthermore, in the internal space S of the vapor chamber 1, it is possible to suppress a state in which the liquid-phase working fluid is not present in the evaporation part, i.e. dry-out, the flow of circulation of the liquid-phase working fluid and the gas-phase working fluid become favorable, and the heat transport improves. Based on such a fact, the vapor chamber 1 can have superior heat transport characteristic.

Furthermore, the gap flow channel part 14 easily takes in the liquid-phase working fluid inside and hardly leaks the liquid-phase working fluid taken inside to outside of the gap flow channel part 14 by the capillary phenomenon. For example, even if the vapor chamber 1 is in any posture, such as a state in which the vapor chamber 1 shown in FIG. 1 inclines 90 degrees within the paper plane, or a state up-side down, the liquid-phase working fluid easily enters the gap flow channel part 14, and the liquid-phase working fluid hardly leaks to outside from the gap flow channel part 14. In this way, the heat transport characteristic of the vapor chamber 1 is superior, due to the flow of circulation of the liquid-phase working fluid and the gas-phase working fluid being favorable, independently of the arrangement state of the vapor chamber 1.

Furthermore, the vapor chamber 1 locally includes the annealed part 50 produced by heating when forming the top face joining part 13a, at a portion adjacent to the top face joining part 13a, rather than the entirety of the vapor chamber 1. The annealed part 50 made by heat treatment causes the mechanical strength of the material to decline. The conventional vapor chamber does not locally provide an annealed part to a portion adjacent to the top face joining part 13a of the vapor chamber 1, but rather provides an annealed part over a wide area of the first metal sheet or the second metal sheet. In this way, compared to conventionally, in the vapor chamber 1, the region of the annealed part 50 is small, and it is possible to suppress a decline in mechanical strength by annealing. For this reason, the vapor chamber 1 can have superior mechanical strength.

In addition, the gap flow channel part 14 preferably has a gap length 14x from the sealed part 14a to the opening part 14b longer than the gap width 14w between the top face abutting part 13b and the inner surface abutting part 21. For the gap flow channel part 14, if the gap length 14x is longer than the gap width 14w, the retention amount of the liquid-phase working fluid in the gap flow channel part 14 increases, and the capillary phenomenon of the gap flow channel part 14 improves. For this reason, the heat transport characteristic of the vapor chamber 1 further improves.

From the viewpoint of improving the heat transport characteristic of the vapor chamber 1, the ratio (14x/14w) of the gap length 14x relative to the gap width 14w is preferably 1.0 or more and 30.0 or less, and more preferably 2.0 or more and 10.0 or less.

In addition, the average value for the gap width 14w of the gap flow channel part 14 is preferably 1.0 μm or more and 100.0 μm or less, more preferably 3.0 μm or more and 50.0 μm or less, and even more preferably 5.0 μm or more and 20.0 μm or less. When the average value of the gap width 14w is 1.0 μm or more, it is possible to easily form the gap flow channel part 14. When the average value of the gap width 14w is 100.0 μm or less, since the capillary phenomenon of the gap flow channel part 14 improves, the heat transport characteristic of the vapor chamber 1 further improves.

In addition, the average value for the gap length 14x of the gap flow channel part 14 is preferably 40.0 μm or more, more preferably 80.0 μm or more, and even more preferably 150.0 μm or more. In addition, the average value of the gap length 14x is preferably 1.0 mm or less, more preferably 500.0 μm or less, and even more preferably 200.0 μm or less. When the average value of the gap length 14x is 40.0 μm or more, since the retention amount of the liquid-phase working fluid in the gap flow channel part 14 increases, and the capillary phenomenon of the gap flow channel part 14 improves, the heat transport characteristic of the vapor chamber 1 further improves. When the average value of the gap length 14x is 1.0 mm or less, it is possible to easily form the gap flow channel part 14.

In addition, it is preferable that, as shown in FIG. 2, the gap flow channel part 14 includes a gap enlarged part 15 at a sealed part 14a side, and the average value of the gap width 15w between the top face abutting part 13b and the inner surface abutting part 21 at the gap enlarged part 15 is larger than the average value of the gap width 14w between the top face abutting part 13b and the inner surface abutting part 21 at the gap flow channel part 14 other than the gap enlarged part 15. When the average value for the gap width 15w of the gap enlarged part 15 is longer than the average value of the gap width 14w between the top face abutting part 13b and the inner surface abutting part 21 at the gap flow channel part 14 other than the gap enlarged part 15, the retention amount of the liquid-phase working fluid in the gap flow channel part 14 and the gap enlarged part 15 increases, and the capillary phenomenon of the gap flow channel part 14 improves. For this reason, the heat transport characteristic of the vapor chamber 1 further improves.

From the viewpoint of improving the heat transport characteristic of the vapor chamber 1, the ratio (15w/14w) of the gap width 15w relative to the gap width 14w is preferably 1.1 or more and 2.0 or less. When the ratio (15w/14w) is 1.1 or more, the heat transport characteristic of the vapor chamber 1 improves. When the ratio (15w/14w) is 2.0 or less, it is possible to easily form the gap enlarged part 15.

In addition, from the viewpoint of improving the heat transport characteristic of the vapor chamber 1, the gap enlarged part 15 is preferably provided at the closest portion of the top face abutting part 13b to the top face joining part 13a as shown in FIG. 2, i.e. at the sealed part 14a. Similarly, from the viewpoint of improving the heat transport characteristic of the vapor chamber 1, the shape of the gap enlarged part 15 is preferably spheroidal, as shown in FIG. 2.

In addition, as shown in FIG. 1, the projecting part 12 preferably extends along the longitudinal direction L1 of the vapor chamber 1. When the projecting part 12 extends along the longitudinal direction L1 of the vapor chamber 1, the distance from the evaporation part 41 toward the condensation part 42 becomes longer, and the recirculation amount of the working fluid increases. For this reason, the heat transport characteristic of the vapor chamber 1 further improves.

In addition, the vapor chamber 1 preferably includes a plurality of top face joining parts 13a at one of the projecting parts 12. When a plurality of the top face joining parts 13a is provided to one projecting part 12, the bonding strength of the first metal sheet 10 and the second metal sheet 20 improves. When a plurality of the top face joining parts 13a is provided to each projecting part 12, the bonding strength of the first metal sheet 10 and the second metal sheet 20 further improves.

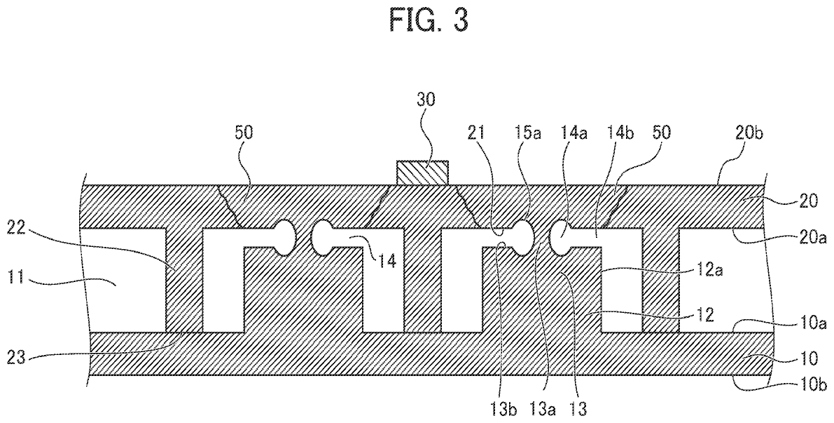

FIG. 3 is an enlarged cross-sectional view showing another example of the second metal sheet 20 constituting the vapor chamber 1. It is preferable that, as shown in FIG. 3, the second metal sheet 20 includes at least one projecting part 22 at the inner surface 20a, and the projecting part 22 of the second metal sheet 20 projects from the inner surface 20a of the second metal sheet 20 toward the first metal sheet 10, and the top face 23 of the projecting part 22 abuts the recessed channel 11 of the first metal sheet 10.

The top face 23 of the projecting part 22 of the second metal sheet 20 abuts the recessed channel 11, i.e. the inner surface 10a of the first metal sheet 10. For this reason, the mechanical strength relative to the thickness direction of the vapor chamber 1 further improves. In addition, the gap due to abutting is provided between the top face 23 of the projecting part 22 and the inner surface 10a of the first metal sheet 10. Since this gap also exhibits the capillary phenomenon relative to the liquid-phase working fluid similarly to the gap flow channel part 14, the liquid-phase working fluid is easily taken in this gap. For this reason, the heat transport characteristic of the vapor chamber 1 further improves.

In addition, the inner surface 10a of the first metal sheet 10 and the inner surface 20a of the second metal sheet 20 preferably have a roughened structure or a groove structure. The roughened structure is formed by roughening treatment on the inner surface 10a or the inner surface 20a. When the inner surface 10a or the inner surface 20a has a roughened structure or a groove structure, the liquid-phase working fluid tends to flow along these structures, and the circulation of the liquid-phase working fluid and the gas-phase working fluid become favorable. For this reason, the heat transport characteristic of the vapor chamber 1 further improves.

In the formation of the top face joining part 13a and the gap flow channel part 14 improving the heat transport characteristic of such a vapor chamber 1, as well as local formation of the annealed part 50, a process using a laser is preferable, and thereamong, a process using a fiber laser is more preferable. In a process by laser, it is possible to suppress formation enlargement of the annealed part 50, and to form the top face joining part 13a and the gap flow channel part 14 into a desired shape in a short time. As a result thereof, the annealed part 50 is not formed over a wide area of the vapor chamber 1, but is rather formed locally. On the other hand, in the joining of the first metal sheet and the second metal sheet by using of diffusion bonding adopted in a conventional vapor chamber, the processability is very low compared to laser processing, such as the formation of the top face joining part 13a and the gap flow channel part 14, particularly the formation of the gap flow channel part 14, being difficult, and the annealed part being formed over the entirety of the vapor chamber.

In addition, the material constituting the first metal sheet 10 and the second metal sheet 20 is preferably copper, copper alloy, aluminum, aluminum alloy or stainless steel, from the viewpoint of high thermal conductivity, processing ease by laser, etc. Thereamong, for the purpose of achieving weight reduction, aluminum or aluminum alloy is more preferable, and for the purpose of raising the mechanical strength, stainless steel is more preferable. In addition, depending on the use environment, tin, tin alloy, titanium, titanium alloy, nickel, nickel alloy, etc. may be used in the first metal sheet 10 and the second metal sheet 20.

The heat generating body 30 mounted to the vapor chamber 1 is a member such as an electronic component which generates heat during operation, such as a semiconductor element, for example.

Next, a manufacturing method of the above-mentioned vapor chamber 1 will be explained.

The manufacturing method of the vapor chamber 1 has a laser bonding step of forming the top face joining part 13a by laser. The laser bonding step preferably forms the top face joining part 13a which joins the first metal sheet 10 and the second metal sheet 20 by a fiber laser. In the laser processing, the top face joining part 13a tends to be process controlled to the desired shape, and the top face joining part 13a can be formed in a short time. Furthermore, in the laser processing, since the portion desired to be joined can be heated locally, the annealed part 50 produced by heating is not formed over a wide area of the vapor chamber 1, but rather is locally formed at a portion adjacent to the top face joining part 13a. Among lasers, the fiber laser is more superior in processing control and short-time processing. When the top face joining part 13a is formed, the gap flow channel part 14 is also formed as a result. Since the step of independently mounting a capillary structure (wick structure) such as conventionally is unnecessary, it is possible to achieve a reduction in production cost and production time, and simplification in production.

More specifically, in a state in which the inner surface 10a of the first metal sheet 10 including the recessed channel 11 and the projecting part 12, and the inner surface 20a of the second metal sheet 20 are opposing each other, and the top face 13 of the projecting part 12 of the first metal sheet 10 is abutting the inner surface 20a of the metal sheet 20, the laser is irradiated to part of the top face 13. For example, the laser may be irradiated from the first metal sheet 10 side to the part of the top face 13, the laser may be irradiated from the second metal sheet 20 side to the part of the top face 13, or the irradiation of these lasers may be combined.

On the other hand, in the joining by diffusion bonding which is adopted in a conventional vapor chamber or the like, the first metal sheet and the second metal sheet are entirely heat treated. In such heat treatment, since the entire surface of the top face 13 of the projecting part 12 is joined to the inner surface of the second metal sheet 20, formation itself of the top face joining part 13a and the gap flow channel part 14 is difficult. For this reason, in addition to the step of joining the first metal sheet and the second metal sheet, it is necessary to separately perform a step of installing a capillary structure. Furthermore, since the first metal sheet and the second metal sheet are entirely annealed by being heat treated, the mechanical strength of the vapor chamber declines.

In addition, the manufacturing method of the vapor chamber 1 preferably further has a laser welding step of welding the outer edge 10c of the first metal sheet 10 and the outer edge 20c of the second metal sheet 20 by laser, before or after the laser processing step. By welding the outer edge 10c of the first metal sheet 10 and the outer edge 20c of the second metal sheet 20 by laser, a welded part 51 is formed, and it is possible to easily manufacture the vapor chamber 1 including the internal space S inside. If the laser used in the laser bonding step and the laser used in the laser welding step are the same, it is possible to easily manufacture the vapor chamber in even shorter time.

More specifically, the laser is irradiated to the first metal sheet 10 and the second metal sheet 20 in a state in which the inner surface 10a of the first metal sheet 10 and the inner surface 20a of the second metal sheet 20 are opposing each other and the outer edge 10c of the first metal sheet 10 and the outer edge 20c of the metal sheet 20 are contacting. For example, the laser may be irradiated to a contacting portion of the outer edge 10c and the outer edge 20c from the first metal sheet 10 side, the laser may be irradiated to a contacting portion of the outer edge 10c and the outer edge 20c from the second metal sheet 20 side, the laser may be irradiated to a contacting portion of the outer edge 10c and the outer edge 20c from an in-plane direction of the vapor chamber 1, or the irradiation of these lasers may be combined.

The vapor chamber 1 manufactured in this way is suitably used in electronic devices such as portable telephones, for which good heat transport characteristics are required even in various postures. The electronic device equipped with the vapor chamber 1 has high heat transport characteristics of the vapor chamber 1, even in various usage states.

According to the above explained embodiment, since the liquid-phase working fluid easily infiltrates and flows in the gap flow channel part, the flow of circulation of the liquid-phase working fluid and the gas-phase working fluid improves, and the heat transfer within the internal space of the vapor chamber increases. For this reason, the vapor chamber can have superior heat transfer characteristics. In addition, in the vapor chamber, the annealed part is not provided over a wide area of the entire body, but rather is locally provided. For this reason, it is possible to suppress a decline in mechanical strength of the vapor chamber due to the annealed part.

It should be noted that, although the above description illustrates an example mounting the heat generating body 30 to the outer surface 20b of the second metal sheet 20 as shown in FIG. 1, the heat generating body 30 may be mounted to the outer surface 10b of the first metal sheet 10.

In addition, it is preferable to install the vapor chamber 1 so that the second metal sheet 20 is arranged on the side of the gravity direction, i.e. so that the second metal sheet 20 is arranged downward and the first metal sheet 10 is arranged upward along the gravity direction. When the vapor chamber 1 is installed so as to arrange the second metal sheet 20 on the gravity direction side, within the internal space S, the gap flow channel part 14 is arranged on the side of the gravity direction. The liquid-phase working fluid tends to enter the gap flow channel part 14 by gravity, in addition to the capillary phenomenon of the gap flow channel part 14. As a result thereof, the heat transport characteristic of the vapor chamber further improves. In such an installation state of the vapor chamber, when mounting the heat generating body 30 on the outer surface 20b of the second metal sheet 20, i.e. lower part of the vapor chamber 1, it is possible to efficiently cool the heat generating body 30.

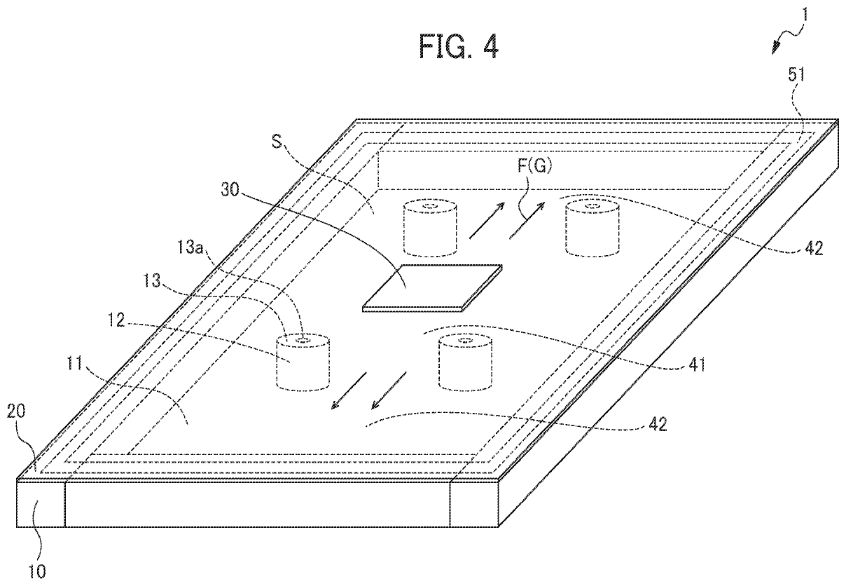

In addition, although the above description illustrates an example in which the projecting part 12 is a square column as shown in FIG. 1, the shape of the projecting part 12 is sufficient so long as the top face 13 can abut the inner surface 20a of the second metal sheet 20. For example, the shape of the projecting part 12 may be a circular column as shown in FIG. 4. In addition, in the case of the first metal sheet 10 including a plurality of the projecting parts 12, the shapes of the projecting parts 12 may all be the same, or at least a part may differ.

### Second Embodiment

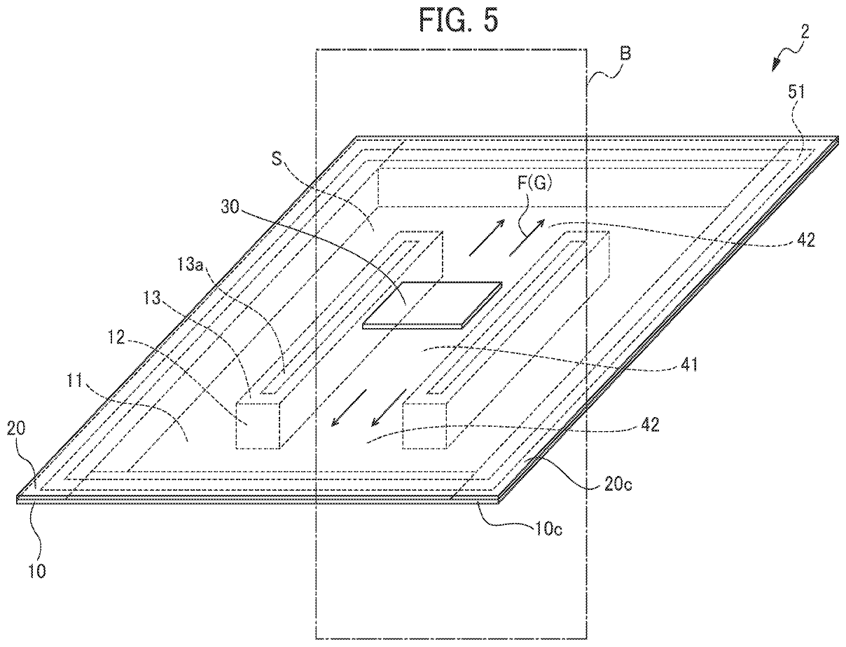

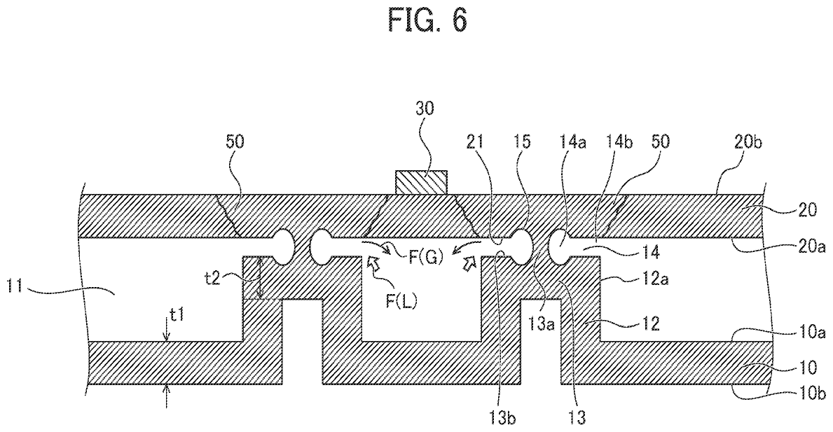

FIG. 5 is a perspective view showing an example of a vapor chamber according to a second embodiment. FIG. 6 is an enlarged cross-sectional view of a plane B in FIG. 5.

It should be noted that, in the embodiment shown below, the same reference numbers are assigned to constituent portions identical to the configuration of the vapor chamber of the first embodiment, and redundant explanations will be omitted or abbreviated.

A vapor chamber 2 according to the second embodiment is basically the same as the configuration of the vapor chamber 1 of the first embodiment, other than the configuration of the first metal sheet 10 differing. For this reason, this differing configuration is mainly explained herein.

As shown in FIGS. 5 and 6, the first metal sheet 10 of the vapor chamber 2 has high uniformity in the sheet thickness, compared to the first metal sheet 10 of the vapor chamber 1 of the first embodiment. In the first metal sheet 10 of the vapor chamber 1, the sheet thickness at the projecting part 12 is clearly larger than the sheet thickness at the recessed channel 11, as shown in FIG. 2.

As shown in FIG. 6, in the vapor chamber 2, the ratio (t2/t1) of the sheet thickness t2 at the projecting part 12 of the first metal sheet 10 relative to the sheet thickness t1 at the recessed channel 11 of the first metal sheet 10 is preferably 0.1 or more and 10.0 or less, more preferably 0.2 or more and 5.0 or less, even more preferably 0.5 or more and 2.0 or less, and most preferably 1.0, i.e. the sheet thickness t1 at the recessed channel 11 and the sheet thickness t2 at the projecting part 12 are equal. When the ratio (t2/t1) is within the above-mentioned range, since the variation in sheet thickness of the first metal sheet 10 is suppressed, it is possible to lighten the weight of the vapor chamber 2. For the formation of the first metal sheet 10 having such a predetermined ratio (t2/t1), processing by press molding is favorable.

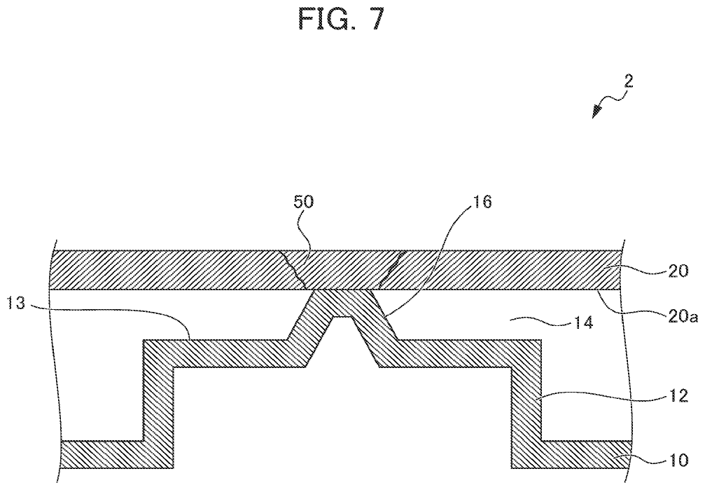

FIG. 7 is an enlarged cross-sectional view showing another example of the projecting part 12 constituting the vapor chamber 2. As shown in FIG. 7, the first metal sheet 10 may further have a convex part 16 which projects from part of the top face 13 toward the inner surface 20a of the second metal sheet 20. The top face of the convex part 16 provided to part of the top face 13 of the projecting part 12 joins to the inner surface 20a of the second metal sheet 20. In this case, part of the top face of the convex part 16 may join to the inner surface 20a of the second metal sheet 20, and the entire surface of the top face of the convex part 16 may join to the inner surface 20a of the second metal sheet 20. A process by press molding is suitable for the formation of the convex part 16.

When the vapor chamber 2 includes the convex part 16, since it is possible to easily control the shape of the gap flow channel part 14, it is possible to easily take the liquid-phase working fluid into the gap flow channel part 14. For this reason, the heat transport characteristic of the vapor chamber can be improved. In addition, compared to the abutting surface area between the top face joining part 13a and the inner surface 20a of the second metal sheet 20 in the vapor chamber not including the convex part 16, it is possible to easily make the abutting surface area between the top face of the convex part 16 and the inner surface 20a of the second metal sheet 20 smaller, and to make the annealed part 50 more locally. For this reason, it is possible to further suppress a decline in mechanical strength of the vapor chamber due to the annealed part.

Next, a manufacturing method of the above-mentioned vapor chamber 2 will be explained.

The manufacturing method of the vapor chamber 2 preferably further has a press processing step of forming the recessed channel 11 and the projecting part 12 of the first metal sheet 10 by press molding, prior to the above-mentioned laser bonding step and the laser welding step. By press molding the first metal sheet 10, it is possible to easily form the recessed channel 11 and the projecting part 12. In the press processing step, it is more preferable to also form the convex part 16 for the first metal sheet 10, in addition to the recessed channel 11 and the projecting part 12.

After the press processing step, by performing the laser welding step following the laser bonding step, or by performing the laser bonding step following the laser welding step, it is possible to manufacture the vapor chamber 2.

According to the above explained embodiment, by making the variation in sheet thickness of the first metal sheet smaller, the vapor chamber can be reduced in weight. The recessed channel and the projecting part of such a first metal sheet can be easily formed in a short time by press molding. For this reason, the vapor chamber can be manufactured more simply.

Although an embodiment has been explained above, the present invention encompasses all aspects included in the gist of the present disclosure and the claims without being limited to the above-mentioned embodiment, and can be modified in various ways within the scope of the present disclosure.

### EXPLANATION OF REFERENCE NUMERALS

1, 2 vapor chamber

10 first metal sheet

10a inner surface of first metal sheet

10b outer surface of first metal sheet

10c outer edge of first metal sheet

11 recessed channel

12 projecting part

12a lateral face of projecting part

13 top face of projecting part

13a top face joining part

13b top face abutting part

14 gap flow channel part

14a sealed part of gap flow channel part

14b opening part of gap flow channel part

15 gap enlarged part

16 convex part

20 second metal sheet

20a inner surface of second metal sheet

20b outer surface of second metal sheet

20c outer edge of second metal sheet

21 inner surface abutting part

22 projecting part

23 top face of projecting part

30 heat generating body

41 evaporation part

42 condensation part

50 annealed part

51 welded part

S internal space

F(L) flow of liquid-phase working fluid

F(G) flow of gas-phase working fluid

1. A vapor chamber having a working fluid in an internal space formed between a first metal sheet and a second metal sheet,
wherein the first metal sheet comprises a recessed channel and at least one projecting part,
wherein the recessed channel is provided at an inner surface of the first metal sheet,
wherein the projecting part projects from the inner surface of the first metal sheet toward the second metal sheet, and a top face of the projecting part abuts the second metal sheet,
wherein the vapor chamber includes at least one top face joining part and gap flow channel part,
wherein the top face joining part joins part of the top face of the projecting part and the second metal sheet, and
wherein the top face and the second metal sheet are separated at the gap flow channel part.

2. The vapor chamber according to claim 1,
wherein the gap flow channel part is provided between a top face abutting part not joined to the second metal sheet in the top face of the first metal sheet, and an inner surface abutting part of the second metal sheet abutting the top face abutting part,
wherein the gap flow channel part has a sealed part at a top face joining part side of the top face abutting part, and
wherein the gap flow channel part has an opening part at a projecting part lateral face side of the top face abutting part.

3. The vapor chamber according to claim 2, wherein the gap flow channel part has a longer gap length from the sealed part to the opening part than a gap width between the top face abutting part and the inner surface abutting part.

4. The vapor chamber according to claim 2, wherein the gap flow channel part has an average value of a gap width between the top face abutting part and the inner surface abutting part of 1.0 μm or more and 100.0 μm or less.

5. The vapor chamber according to claim 2, wherein the gap flow channel part has an average value of a gap length from the sealed part to the opening part of 40.0 μm or more.

6. The vapor chamber according to claim 2,
wherein the gap flow channel part includes a gap enlarged part at a sealed part side, and
wherein an average value of a gap width between the top face abutting part and the inner surface abutting part at the gap enlarged part is larger than an average value of the gap width at the gap flow channel part other than the gap enlarged part.

7. The vapor chamber according to claim 1, wherein a ratio (t2/t1) of a sheet thickness t2 at the projecting part of the first metal sheet relative to a sheet thickness t1 at the recessed channel of the first metal sheet is 0.1 or more and 10.0 or less.

8. The vapor chamber according to claim 1, wherein the projecting part extends along a longitudinal direction of the vapor chamber.

9. The vapor chamber according to claim 1, wherein the vapor chamber includes a plurality of the top face joining parts at one of the projecting parts.

10. The vapor chamber according to claim 1,
wherein the second metal sheet includes at least one projecting part at an inner surface, and
wherein the projecting part of the second metal sheet projects from the inner surface of the second metal sheet toward the first metal sheet, and a top face of the projecting part abuts the recessed channel of the first metal sheet.

11. A manufacturing method of the vapor chamber according to claim 1, the manufacturing method comprising:
a laser bonding step of forming the top face joining part by laser.

12. The manufacturing method of the vapor chamber according to claim 11, further comprising a laser welding step of welding an outer edge of the first metal sheet and an outer edge of the second metal sheet by laser, before or after the laser bonding step.

13. The manufacturing method of the vapor chamber according to claim 11, further comprising a press processing step of forming the recessed channel and the projecting part of the first metal sheet by press molding, prior to the laser bonding step and the laser welding step.

14. The vapor chamber according to claim 3, wherein the gap flow channel part has an average value of a gap width between the top face abutting part and the inner surface abutting part of 1.0 μm or more and 100.0 μm or less.

15. The vapor chamber according to claim 3, wherein the gap flow channel part has an average value of a gap length from the sealed part to the opening part of 40.0 μm or more.

16. The vapor chamber according to claim 3,
wherein the gap flow channel part includes a gap enlarged part at a sealed part side, and
wherein an average value of a gap width between the top face abutting part and the inner surface abutting part at the gap enlarged part is larger than an average value of the gap width at the gap flow channel part other than the gap enlarged part.

17. The vapor chamber according to claim 2, wherein a ratio (t2/t1) of a sheet thickness t2 at the projecting part of the first metal sheet relative to a sheet thickness t1 at the recessed channel of the first metal sheet is 0.1 or more and 10.0 or less.

18. The vapor chamber according to claim 2, wherein the projecting part extends along a longitudinal direction of the vapor chamber.

19. The vapor chamber according to claim 2, wherein the vapor chamber includes a plurality of the top face joining parts at one of the projecting parts.

20. The vapor chamber according to claim 2,
wherein the second metal sheet includes at least one projecting part at an inner surface, and
wherein the projecting part of the second metal sheet projects from the inner surface of the second metal sheet toward the first metal sheet, and a top face of the projecting part abuts the recessed channel of the first metal sheet.
